(19) United States
(12) Patent Application Publication
(10) Pub. No.: US 2025/0351569 A1
(43) Pub. Date: Nov. 13, 2025

(54) DIPOLE-FIRST APPROACH TO FABRICATE A TOP-TIER DEVICE OF A COMPLEMENTARY FIELD EFFECT TRANSISTOR (CFET)

(71) Applicant: Taiwan Semiconductor Manufacturing Company, Ltd., Hsin-Chu (TW)

(72) Inventors: Cheng-Ming Lin, Kaohsiung City (TW); Wei-Yen Woon, Taoyuan City (TW); Szuya Liao, Zhubei Hsinchu (TW)

(21) Appl. No.: 19/277,023

(22) Filed: Jul. 22, 2025

Related U.S. Application Data
(63) Continuation of application No. 18/336,183, filed on Jun. 16, 2023.
(60) Provisional application No. 63/481,712, filed on Jan. 26, 2023.

(51) Int. Cl. H10D 84/85; H10D 64/01; H10D 64/68; H10D 84/01; H10D 84/03

(52) U.S. Cl. CPC H10D 84/856; H10D 64/01; H10D 64/685; H10D 84/0181; H10D 84/038

(57) ABSTRACT

A dipole layer is formed over a semiconductor channel region. A doped gate dielectric layer is formed over the dipole layer. The doped gate dielectric layer contains an amorphous material. Via an annealing process, the amorphous material of the doped gate dielectric layer is converted into a material with at least partially crystal phases. After the doped gate dielectric layer is converted into the layer with partially crystal phases, a metal-containing gate electrode is formed over the doped gate dielectric layer.

### PRIORITY DATA

This present application is a Continuation of U.S. patent application Ser. No. 18/336,183 filed on Jun. 16, 2023 entitled “DIPOLE-FIRST APPROACH TO FABRICATE A TOP-TIER DEVICE OF A COMPLEMENTARY FIELD EFFECT TRANSISTOR (CFET)” which claims benefit of U.S. Provisional Patent Application No. 63/481,712, filed on Jan. 26, 2023, and entitled “BIFUNCTIONAL MATERIAL AS VT SHIFTER OF TOP DEVICE IN SEQUENTIAL CFET”, the disclosure of each of which is hereby incorporated by reference in its respective entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs. For example, high temperature processes performed during the formation of certain IC components may cause damage to other IC components. As a result, the device performance may not be optimal.

Therefore, although conventional methods of fabricating semiconductor devices have generally been adequate, they have not been satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a perspective view of an IC device in the form of a FinFET according to various aspects of the present disclosure.

FIG. 1B is a planar top view of an IC device in the form of a FinFET according to various aspects of the present disclosure.

FIG. 1C is a perspective view of an IC device in the form of a GAA device according to various aspects of the present disclosure.

FIGS. 2-6 are cross-sectional side views illustrating a dipole-first approach to form a gate structure according to various aspects of the present disclosure.

FIGS. 7A-7B are graphs illustrating dipole profiles based on position within the gate structures according to various aspects of the present disclosure.

FIGS. 8-18 are cross-sectional side views illustrating a process flow of forming a CFET device according to various aspects of the present disclosure.

FIG. 19 is a block diagram of a manufacturing system according to various aspects of the present disclosure.

FIG. 20 is a flowchart illustrating a method of fabricating a semiconductor device according to various aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc., as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

The present disclosure is generally related to semiconductor devices, and more particularly to field-effect transistors (FETs), such as three-dimensional fin-shaped FETs (FinFETs) or gate-all-around (GAA) devices. In that regard, a FinFET device is a fin-like field-effect transistor device, and a GAA device is a multi-channel field-effect transistor device. FinFET devices and GAA devices have both been gaining popularity recently in the semiconductor industry, since they offer several advantages over traditional Metal-Oxide Semiconductor Field Effect Transistor (MOSFET) devices (e.g., “planar” transistor devices). These advantages may include better chip area efficiency, improved carrier mobility, and fabrication processing that is compatible with the fabrication processing of planar devices. Thus, it may be desirable to design an integrated circuit (IC) chip using FinFET devices or GAA devices for a portion of, or the entire IC chip. For example, a complementary field effect transistor (CFET) may bond a top-tier device and a bottom-tier device together, where the top-tier device and/or the bottom-tier device may be implemented as GAA devices or FinFET devices.

However, in spite of the advantages offered by the FinFET devices and/or GAA devices, certain challenges may still remain in IC applications in which FinFET or GAA devices are implemented, including in CFET devices. For instance, conventional threshold voltage (Vt) tuning may be done by a dipole drive-in method, which is performed using a relatively high temperature (e.g., greater than about 700 degrees Celsius) to offer a sufficient Vt tuning range. However, a temperature greater than about 500 degrees Celsius is typically not allowed for top-tier device fabrication in a sequential CFET architecture, since that may impact electrical performance (e.g., Vt shifting, Ion degradation, etc.) of the bottom-tier device. In addition, in existing CFET schemes, the high-k (HK) material is mainly amorphous. Amorphous high-k material may not achieve a sufficiently high dielectric constant. As a result, device performance has not been optimized.

To address the issues discussed above, the present disclosure implements a dipole material via a dipole-first approach, which eliminates the need for a high temperature (e.g., at or greater than about 700 degrees Celsius) dipole drive-in process to be performed later. In some embodiments, the dipole material may include yttrium oxide (Y₂O₃). In other embodiments, the dipole material may include scandium oxide (Sc₂O₃). As will be discussed below in more detail, the dipole-first scheme forms the dipole material before a high-k gate dielectric layer. Since no high temperature dipole drive-in process needs to be performed, the potential adverse impact on the bottom-tier device of the CFET is reduced. In addition, the present disclosure forms a doped high-k gate dielectric layer (e.g., an yttrium-doped high-k gate dielectric layer) over the dipole layer. The doped high-k gate dielectric layer can at least partially achieve a crystalline phase (e.g., a cubic phase or a tetragonal phase) in response to an annealing process. The crystalline phase offers the high-k gate dielectric layer of the present disclosure a greater dielectric constant value compared to amorphous gate dielectric layers in conventional implementations. The increased dielectric constant value herein results in an improvement in device performance.

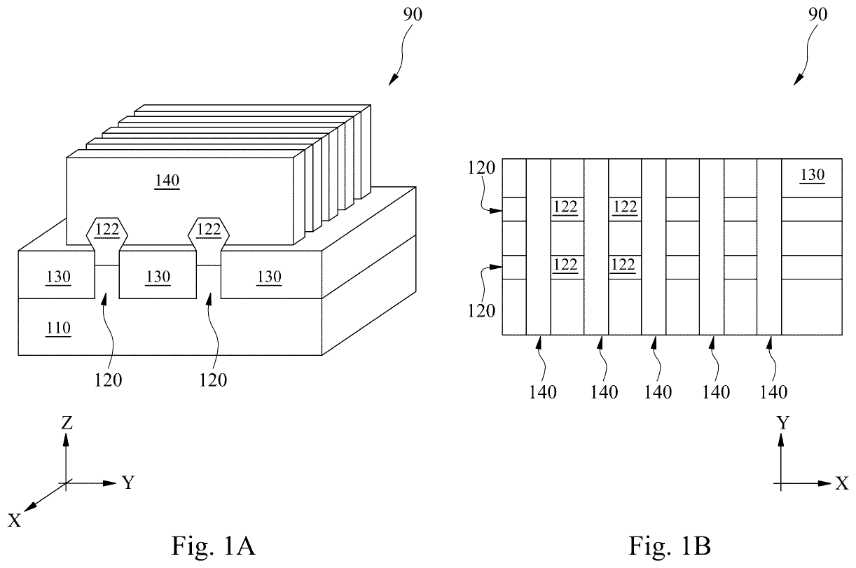

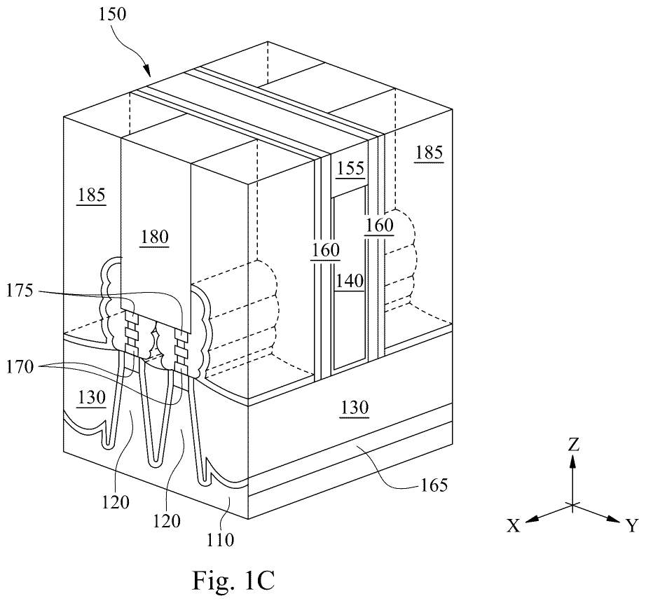

FIGS. 1A-1C will describe the basic structures of example FinFET and GAA devices. Referring now to FIGS. 1A and 1B, a three-dimensional perspective view and a top view of a portion of an Integrated Circuit (IC) device 90 are illustrated, respectively. The IC device 90 may be an intermediate device fabricated during processing of an IC, or a portion thereof, that may comprise static random-access memory (SRAM) and/or other logic circuits, passive components such as resistors, capacitors, and inductors, and active components such as p-type FETs (PFETs), n-type FETs (NFETs), FinFETs, metal-oxide semiconductor field effect transistors (MOSFET), complementary metal-oxide semiconductor (CMOS) transistors, bipolar transistors, high voltage transistors, high frequency transistors, and/or other memory cells. The present disclosure is not limited to any particular number of devices or device regions, or to any particular device configurations, unless otherwise claimed. For example, although the IC device 90 as illustrated is a three-dimensional FinFET device, the concepts of the present disclosure may also apply to planar FET devices or GAA devices.

Referring to FIG. 1A, the 1C device 90 includes a substrate 110. The substrate 110 may comprise an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor such as SiGe, GaAsP, AlInAs, AlGaAs, GaInAs, GaInP, GaInAsP, and/or other suitable materials. The substrate 110 may be a single-layer material having a uniform composition. Alternatively, the substrate 110 may include multiple material layers having similar or different compositions suitable for IC device manufacturing. In one example, the substrate 110 may be a silicon-on-insulator (SOI) substrate having a semiconductor silicon layer formed on a silicon oxide layer. In another example, the substrate 110 may include a conductive layer, a semiconductor layer, a dielectric layer, other layers, or combinations thereof. Various doped regions, such as source/drain regions, may be formed in or on the substrate 110. The doped regions may be doped with n-type dopants, such as phosphorus or arsenic, and/or p-type dopants, such as boron, depending on design requirements. The doped regions may be formed directly on the substrate 110, in a p-well structure, in an n-well structure, in a dual-well structure, or using a raised structure. Doped regions may be formed by implantation of dopant atoms, in-situ doped epitaxial growth, and/or other suitable techniques.

Three-dimensional active regions 120 are formed on the substrate 110. The active regions 120 are elongated fin-like structures that protrude upwardly out of the substrate 110. As such, the active regions 120 may be interchangeably referred to as fin structures 120 hereinafter. The fin structures 120 may be fabricated using suitable processes including photolithography and etch processes. The photolithography process may include forming a photoresist layer overlying the substrate 110, exposing the photoresist to a pattern, performing post-exposure bake processes, and developing the photoresist to form a masking element (not shown) including the resist. The masking element is then used for etching recesses into the substrate 110, leaving the fin structures 120 on the substrate 110. The etching process may include dry etching, wet etching, reactive ion etching (RIE), and/or other suitable processes. In some embodiments, the fin structure 120 may be formed by double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. As an example, a layer may be formed over a substrate and patterned using a photolithography process. Spacers are formed alongside the patterned layer using a self-aligned process. The layer is then removed, and the remaining spacers, or mandrels, may then be used to pattern the fin structures 120.

The IC device 90 also includes source/drain features 122 formed over the fin structures 120. The source/drain features 122 may include epi-layers that are epitaxially grown on the fin structures 120. The IC device 90 further includes isolation structures 130 formed over the substrate 110. The isolation structures 130 electrically separate various components of the IC device 90. The isolation structures 130 may include silicon oxide, silicon nitride, silicon oxynitride, fluoride-doped silicate glass (FSG), a low-k dielectric material, and/or other suitable materials. In some embodiments, the isolation structures 130 may include shallow trench isolation (STI) features. In one embodiment, the isolation structures 130 are formed by etching trenches in the substrate 110 during the formation of the fin structures 120. The trenches may then be filled with an isolating material described above, followed by a chemical mechanical planarization (CMP) process. Other isolation structure such as field oxide, local oxidation of silicon (LOCOS), and/or other suitable structures may also be implemented as the isolation structures 130. Alternatively, the isolation structures 130 may include a multi-layer structure, for example, having one or more thermal oxide liner layers.

The IC device 90 also includes gate structures 140 formed over and engaging the fin structures 120 on three sides in a channel region of each fin 120. The gate structures 140 may be dummy gate structures (e.g., containing an oxide gate dielectric and a polysilicon gate electrode), or they may be HKMG structures that contain a high-k gate dielectric and a metal gate electrode, where the HKMG structures are formed by replacing the dummy gate structures. Though not depicted herein, the gate structure 140 may include additional material layers, such as an interfacial layer over the fin structures 120, a capping layer, other suitable layers, or combinations thereof.

Referring to FIG. 1B, multiple fin structures 120 are oriented lengthwise along the X-direction, and multiple gate structures 140 are oriented lengthwise along the Y-direction, i.e., generally perpendicular to the fin structures 120. In many embodiments, the IC device 90 includes additional features such as gate spacers disposed along sidewalls of the gate structures 140, hard mask layer(s) disposed over the gate structures 140, and numerous other features.

It is also understood that the various aspects of the present disclosure discussed below may apply to multi-channel devices such as Gate-All-Around (GAA) devices. FIG. 1C illustrates a three-dimensional perspective view of an example GAA device 150. For reasons of consistency and clarity, similar components in FIG. 1C and FIGS. 1A-1B will be labeled the same. For example, active regions such as fin structures 120 rise vertically upwards out of the substrate 110 in the Z-direction. The isolation structures 130 provide electrical separation between the fin structures 120. The gate structure 140 is located over the fin structures 120 and over the isolation structures 130. A mask 155 is located over the gate structure 140, and gate spacers 160 are located on sidewalls of the gate structure 140. A capping layer 165 is formed over the fin structures 120 to protect the fin structures 120 from oxidation during the forming of the isolation structures 130.

A plurality of nano-structures 170 is disposed over each of the fin structures 120. The nano-structures 170 may include nano-sheets, nano-tubes, or nano-wires, or some other type of nano-structure that extends horizontally in the X-direction. Portions of the nano-structures 170 under the gate structure 140 may serve as the channels of the GAA device 150. Dielectric inner spacers 175 may be disposed between the nano-structures 170. In addition, although not illustrated for reasons of simplicity, each of the nano-structures 170 may be wrapped around circumferentially by a gate dielectric as well as a gate electrode. In the illustrated embodiment, the portions of the nano-structures 170 outside the gate structure 140 may serve as the source/drain features of the GAA device 150. However, in some embodiments, continuous source/drain features may be epitaxially grown over portions of the fin structures 120 outside of the gate structure 140. Regardless, conductive source/drain contacts 180 may be formed over the source/drain features to provide electrical connectivity thereto. An interlayer dielectric (ILD) 185 is formed over the isolation structures 130 and around the gate structure 140 and the source/drain contacts 180.

Regardless of whether the transistors of an IC are implemented as a FinFET of FIGS. 1A-1B or a GAA device of FIG. 1C, it is understood that they may benefit from the concepts of the present disclosure, as discussed below in more detail.

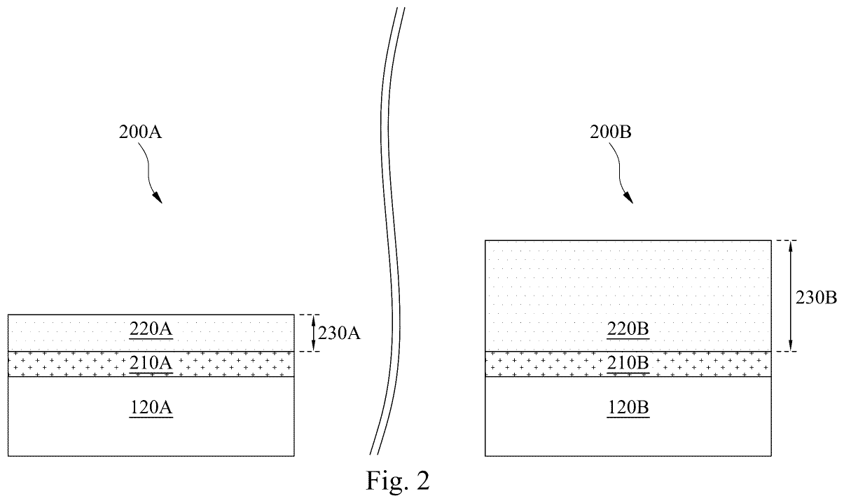

FIGS. 2-6 are a series of diagrammatic fragmentary cross-sectional side views illustrating an example process flow to fabricate example gate structures 200A and 200B according to embodiments of the present disclosure. As a non-limiting example, the gate structure 200A corresponds to an N-type transistor with a high threshold voltage (Vt), whereas the gate structure 200B corresponds to an N-type transistor with a low threshold voltage. In other words, the gate structure 200A is associated with a higher threshold voltage than the gate structure 200B. Hence, the gate structure 200A may belong to a H-NVt (high threshold voltage NFET) device, while the gate structure 200B may belong to a L-NVt (low threshold voltage NFET) device. In some embodiments, the H-NVt device and the L-NVt device may be formed on a same wafer. For example, they may be formed as different circuit components on a same IC. In other embodiments, the H-NVt device and the L-NVt device may be formed on different wafers, for example, as circuit components of different ICs.

Referring now to FIG. 2, The gate structures 200A and 200B are formed over active regions 120A and 120B, respectively. The active regions 120A and 120B maybe embodiments of the active region 120 discussed above with reference to FIG. 1C. For example, the active regions 120A and 120B may include vertically protruding fin structures of a FinFET or a GAA device. In some embodiments, the active regions 120A and 120B may include portions of a channel region of the corresponding transistor. In some embodiments, the channel region may include a III-V group compound. In that regard, the III-V group compound includes an element from the III-group of the periodic table as well as an element from the V-group of the periodic table.

An interfacial layer (IL) 210A and an interfacial layer 210B are formed over the active regions 120A and 120B, respectively. In some embodiments, the interfacial layers 210A and 210B include a group III-V-based oxide.

A dipole layer 220A and a dipole layer 220B are formed over the interfacial layers 210A and 210B, respectively. In the illustrated embodiment, the dipole layers 220A and 220B serve as dipole sources for threshold voltage shifting. Conventionally, a lanthanum-containing material, such as lanthanum oxide, may be used as a dipole source for threshold voltage shifting. Lanthanum oxide has relatively strong threshold voltage shifting properties, which may be well suited for conventional dipole layer designs, since conventional dipole layers are formed over a high-k gate dielectric layer in a “dipole-last” approach. In other words, the high-k gate dielectric layer (and the interfacial layer, if it is implemented) separates the conventional dipole layer from the active region (where the active region is located below the high-k gate dielectric layer), the strong threshold voltage shifting properties of lanthanum oxide can compensate for the distance corresponding to a thickness of the high-k gate dielectric layer.

However, according to the process flow of the present disclosure, the dipole layers 220A and 220B are formed before the formation of gate dielectric layers. In other words, the dipole layers are formed “first” in a “dipole-first” process flow. This means that the dipole layers 220A and 220B herein are much closer to the active regions 120A and 120B below, since they are separated from the active regions 120A and 120B by the interfacial layer 210A and 210B, but not by high-k gate dielectric layers. Consequently, if lanthanum oxide is still used to implement the dipole layers 220A and 220B, then the threshold voltage shifting would have been greater than what is desirable. Therefore, the present disclosure implements the dipole layers 220A and 220B using a material that has weaker threshold voltage shifting properties than lanthanum oxide. In some embodiments, the dipole layers 220A and 220B are implemented using yttrium oxide (Y₂O₃). In other embodiments, the dipole layers 220A and 220B are implemented using scandium oxide (Sc₂O₃).

The dipole layers 220A and 220B may be formed by a suitable deposition process, such as chemical vapor deposition (CVD), physical vapor deposition (PVD), atomic layer deposition (ALD), or combinations thereof. The deposition processes are performed such that the dipole layer 220A has a thickness 230A, and the dipole layer 220B has a thickness 230B. The thicknesses 230A and 230B are each in a range between about 0.1 nanometers (nm) and about 1 nm. However, as shown in FIG. 2, the thickness 230B is greater than the thickness 230A. The reason that the thickness 230B is configured to be greater than the thickness 230A is to account for the fact that the threshold voltage for the gate structure 200B is lower than the threshold voltage for the gate structure 200A.

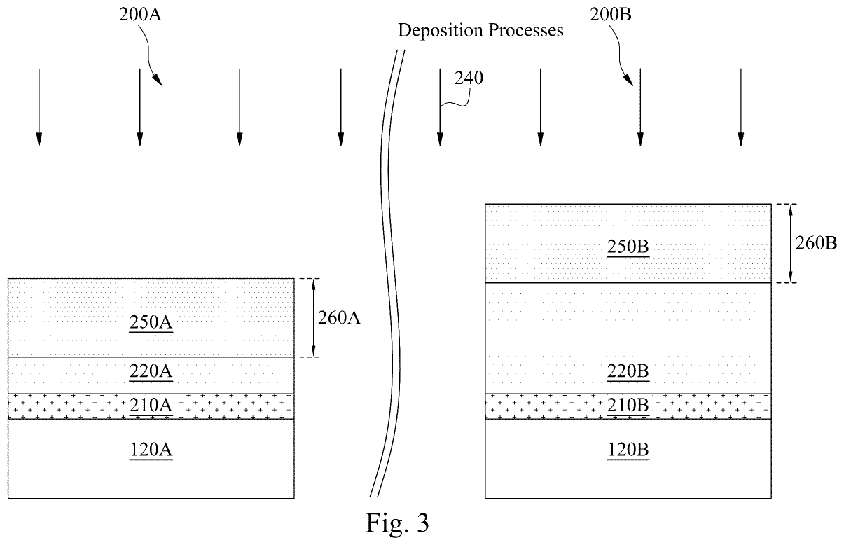

Referring now to FIG. 3, one or more deposition processes 240 are performed to form a gate dielectric layer 250A and a gate dielectric layer 250B over the dipole layers 220A and 220B, respectively. In various embodiments, the deposition processes may include CVD or ALD. The deposition processes 240 are performed such that the gate dielectric layer 250A has a thickness 260A, and the gate dielectric layer 250B has a thickness 260B. In some embodiments, the thicknesses 260A and 260B are each thicker than the respective thicknesses 230A and 230B of the dipole layers 220A and 220B. For example, the thicknesses 260A and 260B may be in a range between about 1 nm and about 5 nms.

The gate dielectric layers 250A and 250B contain high-k dielectric materials, which are dielectric materials that have a dielectric constant greater than a dielectric constant of silicon dioxide. In some embodiments, the gate dielectric layers 250A and 250B include hafnium oxide. In other embodiments, the gate dielectric layers 250A and 250B include zirconium oxide.

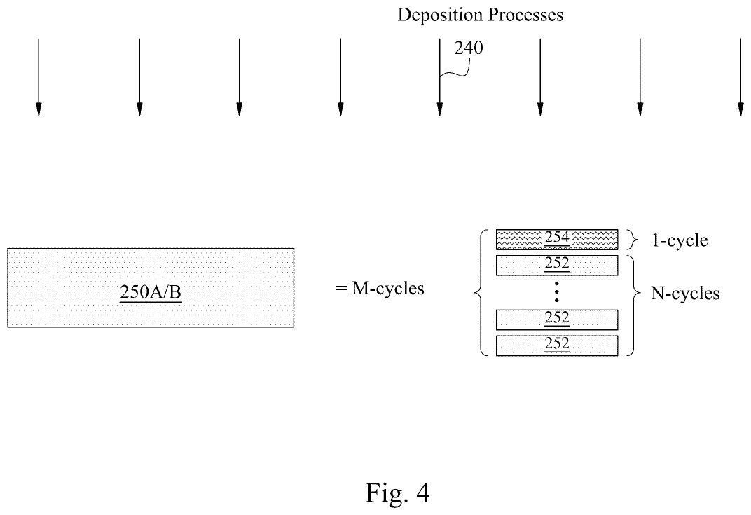

In some embodiments, the gate dielectric layers 250A and 250B are also doped with a dopant. For example, the gate dielectric layers 250A and 250B may be doped with yttrium. The implementation of the dopant material in the gate dielectric layers 250A and 250B may be accomplished by tuning the deposition processes 240. For example, referring now to FIG. 4, the deposition processes 240 may utilize a plurality of deposition cycles to form the gate dielectric layer 250A and/or 250B. In more detail, the deposition processes 240 may include an M-number of repeating cycles, wherein each cycle in the M-number of cycles includes the following cycles:
using an N-number of cycles to deposit N numbers of sub-layers of undoped high-k dielectric material 252; and
using 1 cycle to deposit a dopant-containing material 254, such as yttrium oxide over the uppermost undoped high-k dielectric material 252.

As a simplified example, suppose the number N has a value of 10. In that case, 10 cycles of deposition processes (e.g., CVD or ALD) are performed to form 10 sub-layers of high-k dielectric material 252, which may be initially undoped. As discussed above, the high-k dielectric material 252 may include hafnium oxide in some embodiments, or zirconium oxide in some other embodiments. After the 10^{th} layer of the undoped high-k dielectric material 252 is deposited, another deposition process (e.g., CVD or ALD) is performed to deposit a sub-layer of a dopant-containing material 254 (e.g., an yttrium-containing material such as yttrium oxide) on the 10^{th} sub-layer of the undoped high-k dielectric material 252. At this point, a structure comprising 10 sub-layers of undoped high-k dielectric materials 252 and 1 sub-layer of a dopant-containing material 254 is formed via a single cycle of the M number of cycles.

The above processes may be repeated for an M number of times to form a composite structure that contains an M number of repeating stacks, where each of the repeating stacks includes 10 sub-layers of high-k dielectric materials 252 and 1 sub-layer of the dopant-containing material 254. In this manner, the resulting gate dielectric layer 250A/250B contains both the high-k dielectric material 252, as well as the dopant-containing material 254.

It is understood that the values of M and N may be flexibly configured in various embodiments to fit the design needs and/or fabrication requirements. For example, the greater the value of N is, the lower the concentration of the dopant is in the final gate dielectric layer 250A/B. This is because as N increases, the gate dielectric layer 250A/B will contain more sub-layers of the high-k dielectric material, while the dopant-containing material 254 still remains constant (since 1 sub-layer of the dopant-containing material 254 is deposited for every N number of sub-layers of the high-k dielectric material 252). In other words, the value of N may be configured to tune the concentration level of the dopant (e.g., yttrium oxide) in the gate dielectric layers 250A/B. Meanwhile, the overall thickness (e.g., the thickness 260A/B in FIG. 3) of the gate dielectric layers 250A/B is decided by the value of M. For example, as the value of M increases, the gate dielectric layers 250A/B will become thicker, and vice versa.

It is also understood that there may not be a clear demarcation line between the high-k dielectric materials 252 and the dopant-containing material 254 in the final structure of the gate dielectric layer 250A/B. For example, the dopant (e.g., yttrium oxide) from the dopant-containing material 254 may diffuse into one or more sub-layers of the high-k dielectric materials 252 below. For reasons of simplicity, such a diffusion is not specifically illustrated herein.

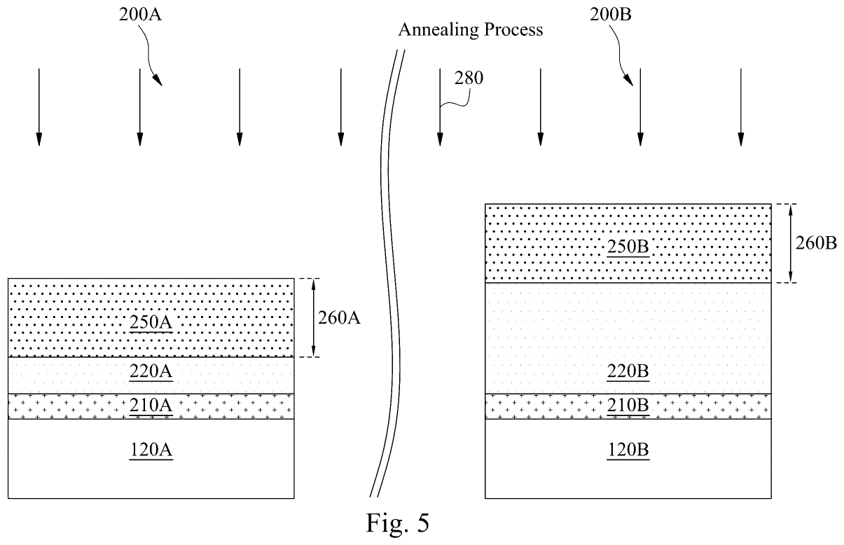

At this stage of fabrication, the gate dielectric layers 250A and 250B are amorphous, which results in a lower-than-optimal dielectric constant value. In order to raise the dielectric constant value, an annealing process will be performed to transform the amorphous material at least partially into a material with a crystalline phase, so that the gate dielectric layers 250A and 250B can achieve a higher dielectric constant value. This is shown in FIG. 5, where an annealing process 280 is performed to convert the amorphous material of the gate dielectric layers 250A and 250B at least partially into a crystal material. In such a conversion process, the dopant-containing material 254 (e.g., yttrium oxide) will help to stabilize the crystal phase of the high-k dielectric materials 252 (e.g., hafnium oxide or zirconium oxide) in the gate dielectric layers 250A and 250B.

In embodiments where the gate dielectric layers 250A and 250B include hafnium oxide, the annealing process 280 converts at least portions of the amorphous hafnium oxide material into a crystalline hafnium oxide material with a cubic crystalline phase. In embodiments where the gate dielectric layers 250A and 250B include zirconium oxide, the annealing process 280 converts at least portions of the amorphous zirconium oxide material into a crystalline zirconium oxide material with a tetragonal crystalline phase.

Regardless of the material compositions and/or the crystalline phases of the gate dielectric layers 250A and 250B (after the annealing process 280 has been performed), it is understood that one benefit of the crystalline phases of the gate dielectric layers 250A and 250B is that they lead to a greater dielectric constant (compared to the amorphous materials of the gate dielectric layers 250A and 250B). The greater dielectric constants of the gate dielectric layers 250A and 250B translate into performance improvements, for example, the case of equivalent oxide thickness (EOT) scaling.

In some embodiments, the annealing process 280 is performed with a temperature that is less than 500 degrees Celsius, for example, in a range between about 400 degrees Celsius and about 500 degrees Celsius. Such a temperature range is specifically configured to minimize damage to the bottom-tier device of a CFET. In more detail, the annealing process 280 herein is performed to gate structures 200A and 200B, which are top-tier devices of the CFET. At this stage of fabrication, the bottom-tier device-which is bonded to the top-tier device-includes transistors that have already been substantially formed. If the temperature of the annealing process 280 is too high (e.g., greater than about 500 degrees Celsius), then such a high temperature could cause damage to the transistor components of the bottom-tier device. Here, by ensuring that the temperature of the annealing process 280 is less than 500 degrees Celsius, potential damage to the bottom-tier device is prevented, or at least minimized.

Note that the relative disposition between the gate dielectric layer 250A and the dipole layer 220A (and likewise, between the gate dielectric layer 250B and the dipole layer 220B) is one of the unique physical characteristics of the devices of the present disclosure, as well as an inherent result of the unique fabrication process flow of the present disclosure performed herein. For example, the unique dipole-first approach of the present disclosure inherently results in the dipole layers 220A/220B being formed below the gate dielectric layers 250A/250B. In contrast, conventional devices have a reverse relative disposition between their dipole layers and gate dielectric layers: their dipole layers are located above the gate dielectric layers, since conventional devices utilize a dipole-last approach. Therefore, if a device is detected to have its dipole layer implemented below its gate dielectric layer, it may be evidence that such a device was fabricated using the unique dipole-first process flow of the present disclosure.

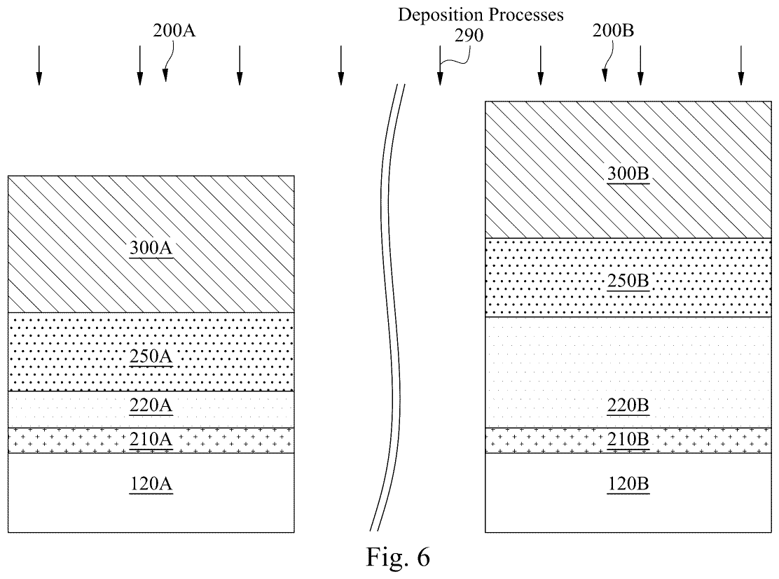

Referring now to FIG. 6, a plurality of deposition processes 290 are performed to form a metal-containing gate electrode 300A over the gate dielectric layer 250A and to form a metal-containing gate electrode 300B over the gate dielectric layer 250B. In some embodiments, the metal-containing gate electrodes 300A and 300B may include work function metal layers and fill metal layers. The work function metal layers may help tune the threshold voltage of the corresponding transistor, and the fill metal layers may serve as a main conductive portion of the gate electrode. In some embodiments, the metal-containing gate electrodes 300A and 300B make contain pure metals, such as titanium (Ti), aluminum (Al), tungsten (W), tantalum (Ta), etc. In some other embodiments, the metal-containing gate electrodes 300A and 300B make contain metal compounds, such as tantalum nitride (TaN), titanium nitride (TiN), titanium aluminum (TiAl), tungsten nitride (WN), etc.

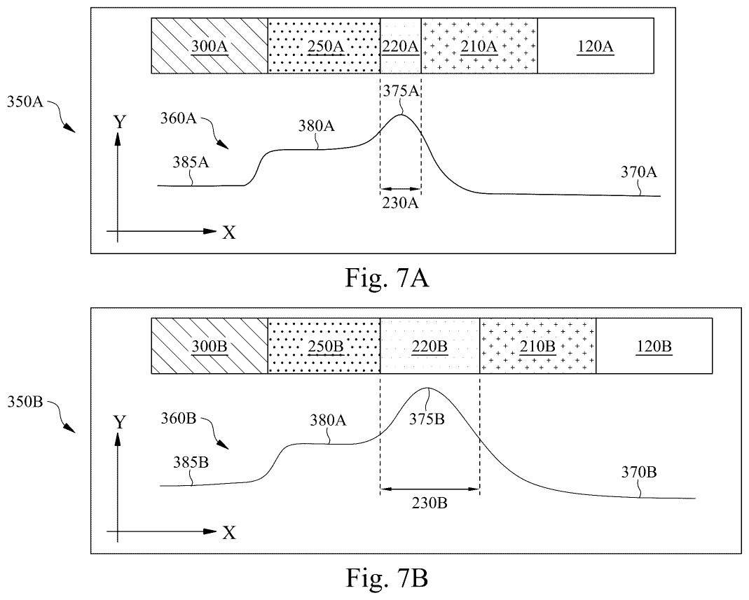

FIGS. 7A-7B illustrate a graph 350A and a graph 350B, respectively. The graphs 350A and 350B plots the variations of yttrium concentration 360A and 360B throughout the gate structures 200A and 200B, respectively. For example, the graphs 350A and 350B each include an X-axis and a Y-axis. The X-axis of FIGS. 7A-7B represents the vertical position (or depth) within the gate structures 200A-200B. In other words, the X-axis of FIGS. 7A-7B correspond to the vertical direction in FIGS. 2-6. Meanwhile, the Y-axis of FIGS. 7A-7B represents the concentration of yttrium in the gate structures 200A-200B.

As shown in the graph 350A, going from right to left on the X-axis (i.e., representing going from a deeper depth to a shallower depth within the gate structure 200A), the yttrium concentration 360A starts off at a relatively low level 370A and remains relatively flat throughout the active region 120A and most of the interfacial layer 210A. The yttrium concentration 360A begins to rise rapidly near the interface between the interfacial layer 210A and the dipole layer 220A, reaches a peak 375A near a mid-point within the dipole layer 220A, and thereafter begins to drop, until another plateau 380A is reached in the gate dielectric layer 250A. The yttrium concentration 360A remains at or near the plateau 380A throughout most of the gate dielectric layer 250A, and then it begins to drop off rapidly past the interface between the gate dielectric layer 250A and the metal-containing gate electrode 300A. The yttrium concentration 360A reaches another plateau 385A within the metal-containing gate electrode 300A.

The behavior of the yttrium concentration 360A illustrated in FIG. 7A makes intuitive sense, since the dipole layer 220A (where the peak 375A resides) is made of yttrium oxide in the illustrated embodiment and therefore contains the greatest level of yttrium. The fact that the gate dielectric layer 250A has the second greatest yttrium concentration level (i.e., below that of the dipole layer 220A but above that of the metal-containing gate electrode 300A) is due to the gate dielectric layer 250A being doped with yttrium, but is still comprised mostly of a high-k dielectric material (e.g., hafnium oxide or zirconium oxide). The metal-containing gate electrode 300A and the active regions 120A contain low levels of yttrium, because they are not made of yttrium, nor are they directly doped with yttrium. The amount of yttrium in the metal-containing gate electrode 300A and the active regions 120A are due to diffusion, where the yttrium is diffused into these layers from the dipole layer 220A and/or from the doped gate dielectric layer 250A.

The yttrium concentration 360B illustrated in FIG. 7B varies in a manner that is similar to the yttrium concentration 360A illustrated in FIG. 7A. For example, the yttrium concentration 360B also starts off relatively low at a level 370B, reaches a peak 375B within the dipole layer 220B, drops off to a lower plateau 380A within the gate dielectric layer 250B, and drops and settles to an even lower plateau 385B within the metal-containing gate electrode 300B. One difference between the yttrium concentration 360A of FIG. 7A and the yttrium concentration 360A of FIG. 7B is that a wider band exists around the peak 375B than around the peak 375A. This is because the dipole layer 220B is thicker than the dipole layer 220A.

In some embodiments, a ratio between the yttrium concentration levels corresponding to the peak 375A and the plateau level 380A is in a range between about 2% and about 10%, and a ratio between the yttrium concentration levels corresponding to the plateau level 380A and the plateau level 385A is in a range between about 0% and about 2%. Similar ratio ranges may apply to the peak 375B, the plateau level 380A, and the plateau level 385B of FIG. 7B.

It is understood that the yttrium concentration profiles illustrated in FIGS. 7A-7B—including the above ratio ranges—are actual physical characteristics of the devices manufactured according to the process flow of the present disclosure and may be detectable. For example, they may be detected using machines such as an Energy Dispersive Spectroscopy (EDS) tool, an Electron energy loss spectroscopy (EELS) tool, a Secondary-Ion Mass Spectrometry (SIMS) tool, etc. These detectable yttrium concentration profiles are inherent results of the performance of the unique dipole-first process flows of the present disclosure. For example, the dipole-first scheme utilized by the present disclosure inherently results in the peak concentration of the yttrium at or near a region between the gate dielectric layer 250A/B and the interfacial layer 210A/B, which corresponds to the location of the dipole layer 220A/B in the illustrated embodiment. In contrast, the profile of the dipole material (which may be a lanthanum-containing material) in conventional devices would have occurred at or near an interface between a gate dielectric layer and a metal-containing gate electrode. In addition, the fact that the gate dielectric layers 250A/250B are doped with yttrium means that the yttrium levels corresponding to the location of these layers are higher than the metal-containing gate electrodes 300A/300B, the interfacial layers 210A/210B, or the active regions 120A/120B, but not as high as the dipole layers 220A/220B. As such, devices exhibiting the yttrium concentration profiles shown in FIGS. 7A-7B may be used as evidence that those devices were manufactured using the process flows of the present disclosure.

It is also understood that although yttrium is used herein to describe the dipole profile of example devices of the present disclosure, it is not intended to be limiting. In other embodiments, scandium oxide (instead of yttrium oxide) may be used to implement the dipole layer 220A/220B. In these embodiments, the profiles illustrated in FIGS. 7A-7B may still exist and may be detectable, though the concentration levels would be those of scandium, rather than yttrium.

It is understood that although the examples herein correspond to N-type transistors, the same concepts may apply to P-type transistors as well. For example, the dipole-first approach discussed above may also be used to form a P-dipole layer over an active region of a P-type transistor, a doped gate dielectric layer may then be formed over the P-dipole layer, followed by an annealing process to convert amorphous materials of the doped gate dielectric layer at least partially into materials with crystalline phases, and a metal-containing gate electrode may then be formed over the gate dielectric layer. Regardless of whether the concepts of the present disclosure are used to form an N-type transistor or a P-type transistor, the same benefits may be achieved. For example, damage to the bottom-tier device may be avoided, and the device performance may be improved by raising the dielectric constant values (e.g., by converting amorphous materials into crystal materials).

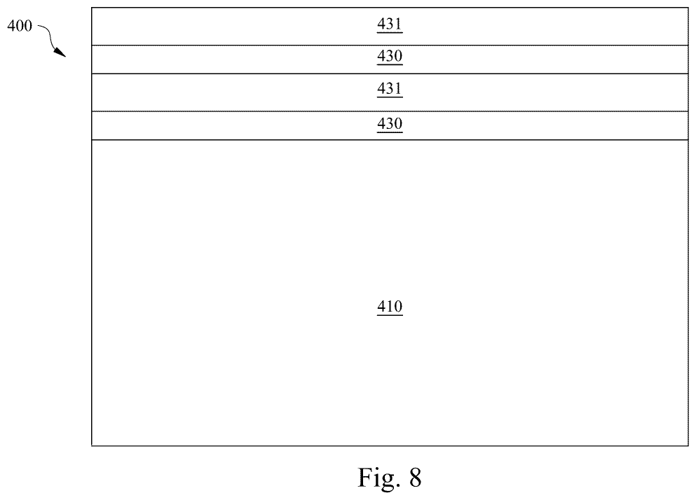

FIGS. 8-19 are a series of diagrammatic fragmentary cross-sectional side views illustrating an example process flow to fabricate a sequential CFET 400 according to embodiments of the present disclosure. Referring to FIG. 8, the CFET 400 includes a substrate 410, which may be an embodiment of the substrate 110 discussed above. In some embodiments, the substrate 410 may be a silicon substrate. A plurality of alternating semiconductor layers 430 and 431 are formed over the substrate 410. In some embodiments, the semiconductor layers 430 include silicon germanium (SiGe), and the semiconductor layers 431 include silicon (Si). Note that although FIG. 8 illustrates two semiconductor layers 430 and two semiconductor layers 431, any other number (e.g., three or more) of semiconductor layers 430 and 431 may be implemented in other embodiments.

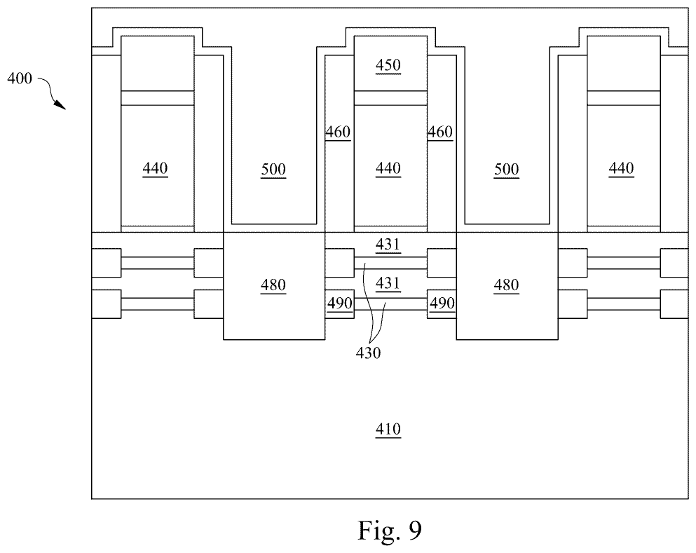

Referring to FIG. 9, other processes may be performed to continue the fabrication of the CFET 400, such as fin structure patterning, shallow trench isolation (STI) formation, gate patterning, spacer deposition, source/drain etching, inner spacer formation, bottom source/drain epitaxial formation, contact-etching stop layer (CESL) formation, and interlayer dielectric (ILD0) formation, etc. As a result of these fabrication processes, portions of the semiconductor layers 431 are patterned into nano-structure channels 431, for example, as nano-sheets, nano-tubes, nano-wires, etc. Dummy gate structures 440 are formed over the uppermost one of the nano-structure channels 431. In some embodiments, the dummy gate structures 440 may include a polysilicon dummy gate electrode. Each dummy gate structure 440 may be patterned by one or more hard mask layers 450, which may include one or more dielectric materials. Gate spacers 460 are formed on sidewalls of the dummy gate structure 440. The gate spacers 460 may also include a suitable dielectric material. In some embodiments, each of the gate spacers 460 may include a plurality of gate spacer layers, but this is not specifically illustrated herein for reasons of simplicity.

Source/drain regions 480 are also formed (e.g., via epitaxial growth) by these fabrication processes. As used herein, the source/drain region 480, or “S/D region,” may refer to a source or a drain of a transistor device. It may also refer to a region that provides a source and/or drain for multiple transistor devices. Inner spacers 490 are formed between the source/drain regions 480 and the semiconductor layers 430. The inner spacers 490 may also include a suitable dielectric material. An ILD0 500 is also formed over the source/drain regions 480 and between the dummy gate structures 440. The ILD0 500 includes a suitable dielectric material to provide electrical isolation between various microelectronic components of the CFET 400. The ILD0 500 may be planarized by a chemical mechanical polishing (CMP) process to flatten its upper surface.

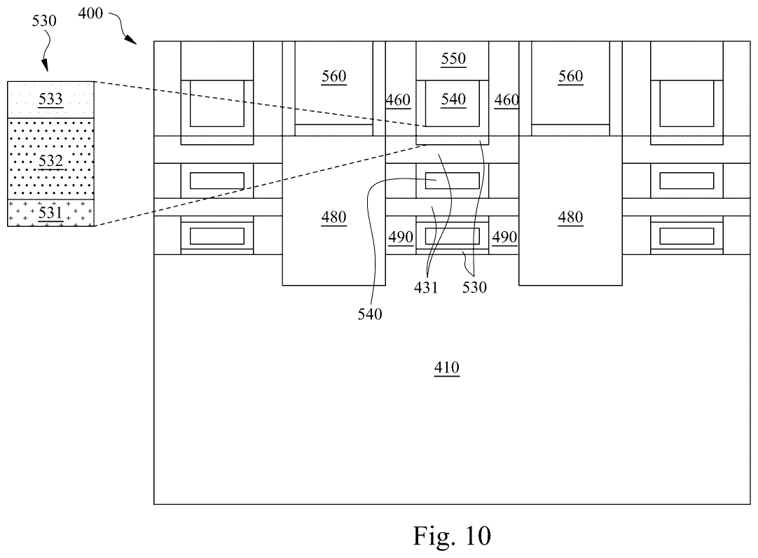

Referring now to FIG. 10, the dummy gate structures 440 are removed. The semiconductor layers 430 (e.g., containing SiGe) are also removed. Gate dielectric structures 530 and gate electrodes 540 are formed to replace the removed semiconductor layers 430 and the removed dummy gate structures 440. In some embodiments, the gate dielectric structures 530 may be formed by a dipole-last approach. The details of one of the gate dielectric structures 530 are also illustrated in a magnified cross-sectional side view in FIG. 10. For example, the gate dielectric structure 530 may include an interfacial layer 531, a high-k dielectric layer 532 formed over the interfacial layer 531, and a dipole layer 533 formed over the high-k dielectric layer 532. In some embodiments, the high-k dielectric layer 532 includes hafnium oxide, zirconium oxide, or another suitable dielectric material having a dielectric constant greater than that of silicon dioxide. In some embodiments, the dipole layer 533 includes a lanthanum-containing material, such as lanthanum oxide.

Although the dipole-last approach is used to form the gate dielectric structure 530 in the illustrated embodiment, it is understood that the dipole-first approach discussed above with FIGS. 2-6 may alternatively be used to implement the gate dielectric structure 530 in other embodiments. In these alternative embodiments, the gate dielectric structure 530 would include a dipole layer (e.g., yttrium oxide or scandium oxide) that is located below the high-k dielectric layer.

Regardless of which approach is used to form the gate dielectric structure 530, the gate electrode 540 is formed over the gate dielectric structure 530. The gate electrode 540 may include metal materials, for example, work function metal materials and fill metal materials. In other words, the gate electrode 540 may be similar to the gate electrodes 300A-300B discussed above. A self-aligned contact (SAC) 550 may also be formed over an uppermost surface of the gate electrode 540. Source/drain contacts 560 are formed over the source/drain regions 480 to provide electrical connectivity to the source/drain regions 480.

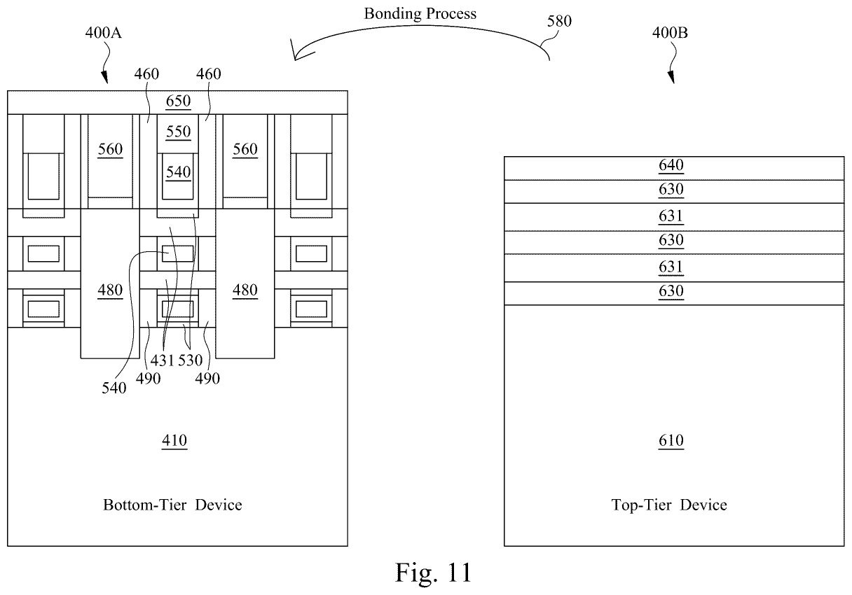

It is understood that the microelectronic components discussed above with reference to FIGS. 8-10 are components of a bottom-tier device 400A of a CFET. Referring now to FIG. 11, a bonding process 580 is performed to bond a top-tier device 400B of the CFET to the bottom-tier device 400A. In more detail, the top-tier device 400B includes a substrate 610, which may be an embodiment of the substrate 210 discussed above. In some embodiments, the substrate 610 may be similar to the substrate 410. For example, the substrates 410 and 610 may both be silicon substrates.

The top-tier device 400B also includes a plurality of alternating semiconductor layers 630 and 631 formed over the substrate 610. In some embodiments, the semiconductor layers 430 include silicon germanium (SiGe), and the semiconductor layers 431 include silicon (Si). Note that although FIG. 11 illustrates three semiconductor layers 630 and two semiconductor layers 631, any other number (e.g., four or more) of semiconductor layers 630 and 631 may be implemented in other embodiments.

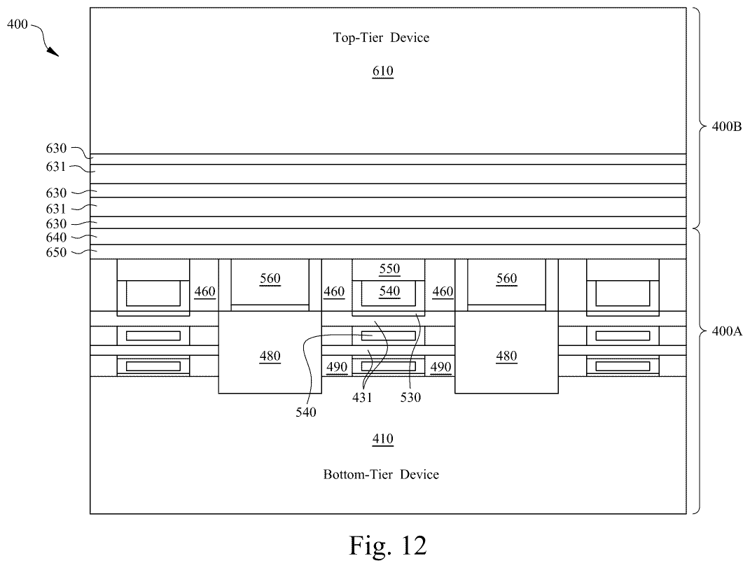

Before the bonding process 580 is formed, a bonding layer 640 and a bonding layer 650 are formed over the topmost surfaces of the top-tier device 400B and the bottom-tier device 400A, respectively. The bonding process 580 then bonds the top-tier device 400B to the bottom-tier device 400A via the bonding layers 640 and 650. In other words, the exposed surface of the bonding layer 640 is bonded to the exposed surface of the bonding layer 650. Note that the top-tier device 400B may be vertically “flipped over” after being bonded to the bottom-tier device 400A, as shown in FIG. 12.

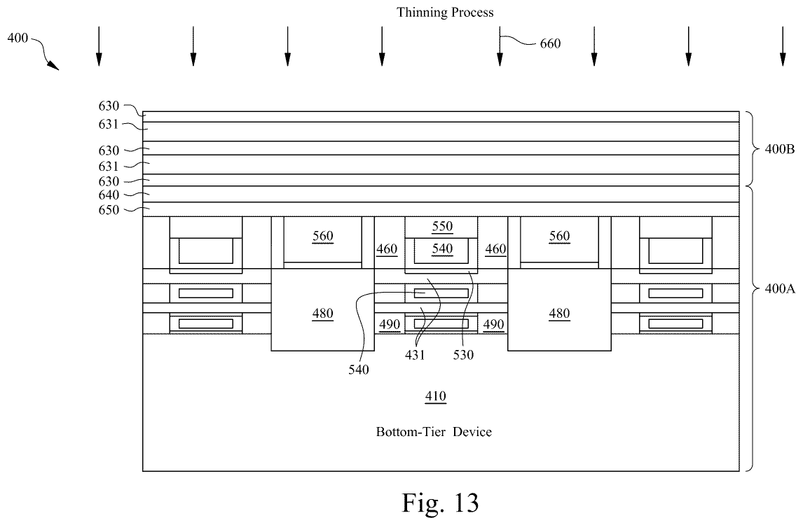

Referring now to FIG. 13, a thinning process 660 is performed to remove the substrate 610 of the top-tier device 400B. in some embodiments, the thinning process 660 may include an etching process, a mechanical grinding process, or combinations thereof. The thinning process 660 may be performed until the topmost semiconductor layer 630 is exposed.

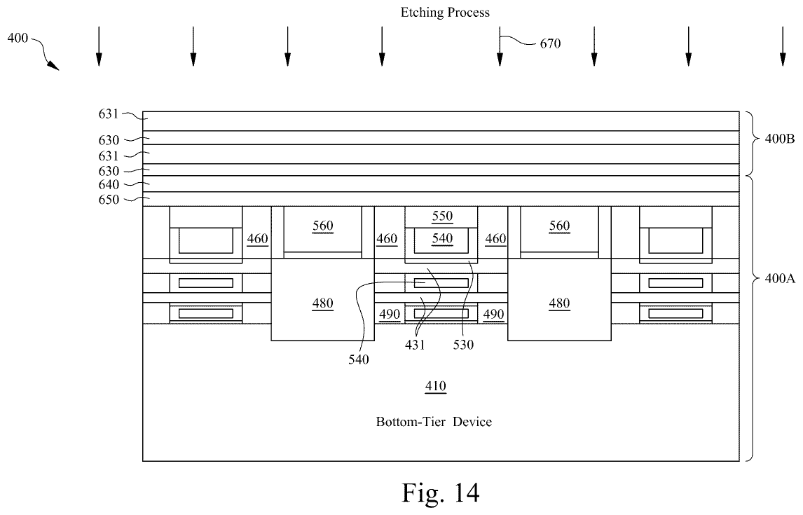

Referring now to FIG. 14, an etching process 670 is performed to remove the uppermost one of the semiconductor layers 630. The semiconductor layer 631 serves as an etching-stop layer, such that the etching process 670 stops when an upper surface of the semiconductor layer 631 is reached.

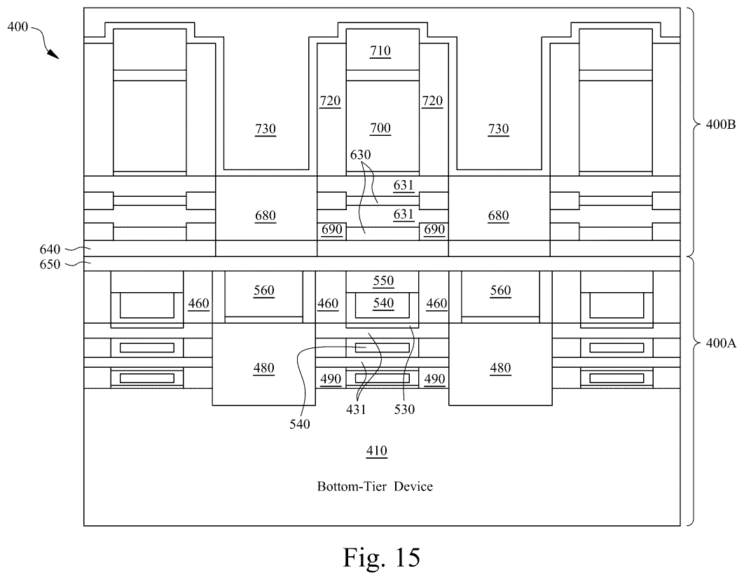

Referring now to FIG. 15, a plurality of processes may be performed to continue the fabrication of the top-tier device 400B of the CFET 400. Source/drain regions 680 are also formed, for example, via epitaxial growth. As used herein, the source/drain region 680, or “S/D region,” may refer to a source or a drain of a transistor device. It may also refer to a region that provides a source and/or drain for multiple transistor devices. Inner spacers 690 are formed between the source/drain regions 680 and the semiconductor layers 630. The inner spacers 490 may also include a suitable dielectric material. In some embodiments, the locations of the source/drain regions 680 of the top-tier device 400B are vertically aligned with the locations of the source/drain regions 480 of the bottom-tier device 400A, respectively.

Dummy gate structures 700 are formed over the uppermost one of the nano-structure channels 631. In some embodiments, the dummy gate structures 700 may include a polysilicon dummy gate electrode. Each dummy gate structure 700 may be patterned by one or more hard mask layers 710, which may include one or more dielectric materials. Gate spacers 720 are formed on sidewalls of each of the dummy gate structures 700. The gate spacers 720 may also include a suitable dielectric material. In some embodiments, each of the gate spacers 720 may include a plurality of gate spacer layers, but this is not specifically illustrated herein for reasons of simplicity.

An ILD1 730 is also formed over the source/drain regions 680 and between the dummy gate structures 700. The ILD1 730 includes a suitable dielectric material to provide electrical isolation between various microelectronic components of the top-tier device 400B of the CFET 400. The ILD1 730 may be planarized by a chemical mechanical polishing (CMP) process to flatten its upper surface.

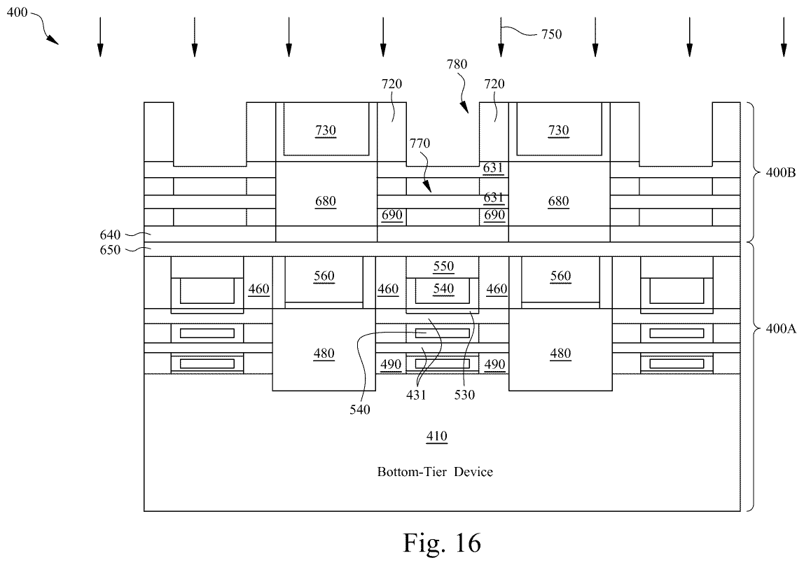

Referring now to FIG. 16, one or more processes 750 may be performed to remove the dummy gate structures 700 and the semiconductor layers 630 from the top-tier device 400B of the CFET 400. For example, the one or more processes 750 may include etching processes. The etching processes may be configured to have an etching selectivity between the semiconductor layers 630 and the semiconductor layers 631, so that the semiconductor layers 631 are substantially unaffected while the semiconductor layers 630 are removed. The remaining portions of the semiconductor layers 631 form nano-structure channels 631, for example, as nano-sheets, nano-tubes, nano-wires, etc. The gate spacers 720 also remain, as well as portions of the ILD1 730. It can be seen in FIG. 16 that the removal of the semiconductor layers 630 and the dummy gate structures 700 form openings 770 and 780 in the top-tier device 400B.

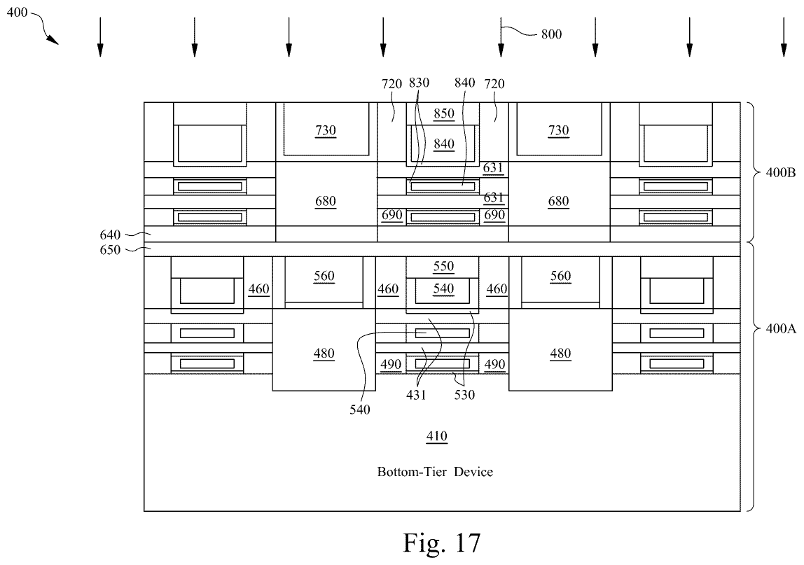

Referring now to FIG. 17, a gate formation process 800 is performed to form metal-containing gate structures to fill the openings 770 and 780. For example, the metal-containing gate structures may each include a gate dielectric structure 830 and a metal-containing gate electrode 840 that is formed over the gate dielectric structure 830. According to various aspects of the present disclosure, the gate dielectric structure 830 is formed using the processes discussed above with reference to FIGS. 2-6. For example, the gate dielectric structure 830 may include an interfacial layer (e.g., an embodiment of the interfacial layer 210A/210B), a dipole layer (e.g., an embodiment of the dipole layer 220A/220B) formed over the interfacial layer, and a doped high-k gate dielectric layer (e.g., an embodiment of the gate dielectric layer 250A/250B) formed over the dipole layer. In other words, the dipole layer of the gate dielectric structure 830 is formed using the dipole-first approach discussed above. For reasons of simplicity, these different layers of the gate dielectric structure 830 are not separately illustrated in FIG. 17.

In any case, it is understood that the dipole layer of the gate dielectric structure 830 include a dipole material that has weaker threshold voltage tuning properties than lanthanum oxide. For example, the dipole material of the gate dielectric structure 830 may include yttrium oxide or scandium oxide. These materials are better suited for tuning the threshold voltages for the top-tier device 400B herein, since the dipole-first approach means that the dipole layer is located closer to the nano-structure channels 631 of the top-tier device 400B. In addition, the dipole-first approach means that no high-temperature dipole drive-in process needs to be performed. The process temperature of the annealing process (e.g., performed to convert the amorphous material of the high-k gate dielectric into a crystalline phase material) is sufficiently low (e.g., at or below about 500 degrees Celsius) to prevent or at least reduce potential damage to the microelectronic components of the bottom-tier device 400A. The conversion of the amorphous material into the crystalline phase material (e.g., hafnium oxide with a cubic phase or zirconium oxide with a tetragonal phase) also helps to increase the dielectric constant of the high-k gate dielectric layer. As such, device performance of the top-tier device 400B and/or the case of EOT scaling may be improved.

The gate electrodes 840 may include metal materials, for example, work function metal materials and fill metal materials. In other words, the gate electrode 840 may be similar to the gate electrodes 300A-300B discussed above. A self-aligned contact (SAC) 850 may also be formed over an uppermost surface of the gate electrode 840.

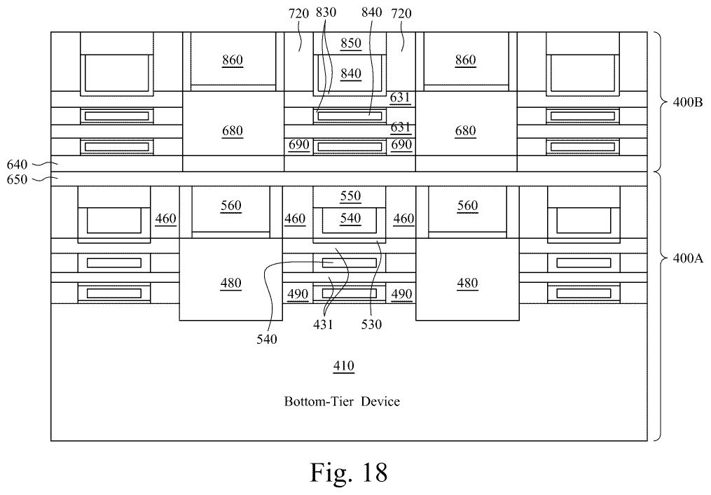

Referring now to FIG. 18, the portions of the ILD1 730 formed over the source/drain regions 680 are removed. Source/drain contacts 860 are formed over the source/drain regions 680 to provide electrical connectivity to the source/drain regions 680. It is understood that additional processes may be performed to continue the fabrication of the CFET 400. for example, conductive gate contacts may be formed to provide electrical connectivity to the gate electrodes 840. Packaging processes may also be formed to continue the packaging of the CFET 400.

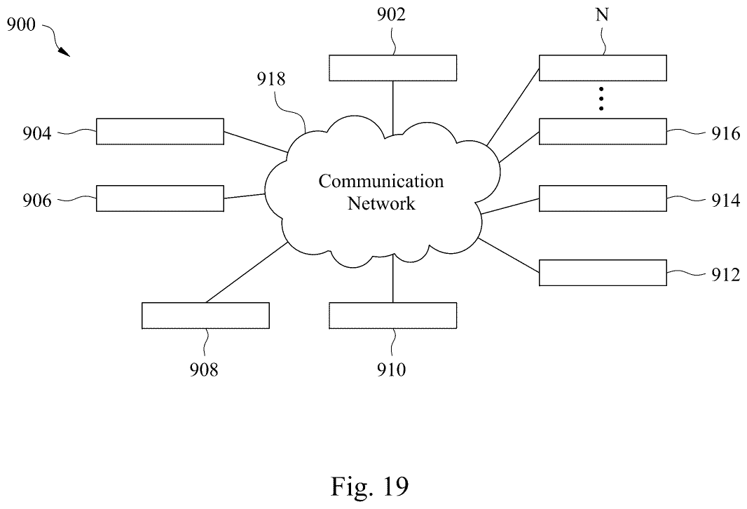

FIG. 19 illustrates an integrated circuit fabrication system 900 that may be used to fabricate the CFET 400 according to embodiments of the present disclosure. The fabrication system 900 includes a plurality of entities 902, 904, 906, 908, 910, 912, 914, 916 . . . , N that are connected by a communications network 918. The network 918 may be a single network or may be a variety of different networks, such as an intranet and the Internet, and may include both wire line and wireless communication channels.

In an embodiment, the entity 902 represents a service system for manufacturing collaboration; the entity 904 represents an user, such as product engineer monitoring the interested products; the entity 906 represents an engineer, such as a processing engineer to control process and the relevant recipes, or an equipment engineer to monitor or tune the conditions and setting of the processing tools; the entity 908 represents a metrology tool for IC testing and measurement; the entity 910 represents a semiconductor processing tool, such an EUV tool that is used to perform lithography processes to define the gate spacers of an SRAM device; the entity 912 represents a virtual metrology module associated with the processing tool 910; the entity 914 represents an advanced processing control module associated with the processing tool 910 and additionally other processing tools; and the entity 916 represents a sampling module associated with the processing tool 910.

Each entity may interact with other entities and may provide integrated circuit fabrication, processing control, and/or calculating capability to and/or receive such capabilities from the other entities. Each entity may also include one or more computer systems for performing calculations and carrying out automations. For example, the advanced processing control module of the entity 914 may include a plurality of computer hardware having software instructions encoded therein. The computer hardware may include hard drives, flash drives, CD-ROMs, RAM memory, display devices (e.g., monitors), input/output device (e.g., mouse and keyboard). The software instructions may be written in any suitable programming language and may be designed to carry out specific tasks.

The integrated circuit fabrication system 900 enables interaction among the entities for the purpose of integrated circuit (IC) manufacturing, as well as the advanced processing control of the IC manufacturing. In an embodiment, the advanced processing control includes adjusting the processing conditions, settings, and/or recipes of one processing tool applicable to the relevant wafers according to the metrology results.

In another embodiment, the metrology results are measured from a subset of processed wafers according to an optimal sampling rate determined based on the process quality and/or product quality. In yet another embodiment, the metrology results are measured from chosen fields and points of the subset of processed wafers according to an optimal sampling field/point determined based on various characteristics of the process quality and/or product quality.

One of the capabilities provided by the IC fabrication system 900 may enable collaboration and information access in such areas as design, engineering, and processing, metrology, and advanced processing control. Another capability provided by the IC fabrication system 900 may integrate systems between facilities, such as between the metrology tool and the processing tool. Such integration enables facilities to coordinate their activities. For example, integrating the metrology tool and the processing tool may enable manufacturing information to be incorporated more efficiently into the fabrication process or the APC module, and may enable wafer data from the online or in site measurement with the metrology tool integrated in the associated processing tool.

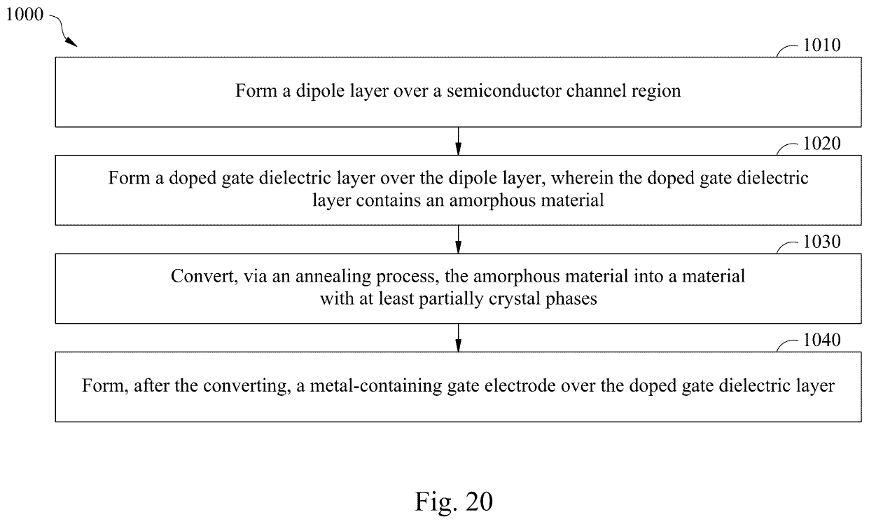

FIG. 20 is a flowchart of a method 1000 of fabricating a semiconductor device according to various aspects of the present disclosure. The method 1000 includes a step 1010 to form a dipole layer over a semiconductor channel region. In some embodiments, the step 1010 of forming the dipole layer comprises depositing an yttrium oxide layer or a scandium oxide layer as the dipole layer

The method 1000 includes a step 1020 to form a doped gate dielectric layer over the dipole layer. The doped gate dielectric layer contains an amorphous material. In some embodiments, the step 1020 of forming the doped gate dielectric layer comprises forming an yttrium-doped gate dielectric layer. In some embodiments, the step 1020 of forming the doped gate dielectric layer comprises performing a first number of deposition cycles. Each cycle of the first number of deposition cycles comprises: depositing a sub-layer of undoped gate dielectric material, wherein the undoped gate dielectric material has a dielectric constant that is greater than a dielectric constant of silicon dioxide; repeating the depositing of the sub-layer for a second number of times; and depositing an yttrium oxide layer over an uppermost one of the sub-layers of the undoped gate dielectric material.

The method 1000 includes a step 1030 to convert, via an annealing process, the amorphous material of the doped gate dielectric layer into a material with partially crystalline phases. In some embodiments, the step 1020 of forming the doped gate dielectric layer comprises forming a doped hafnium oxide layer, and the step 1030 of converting comprises converting the doped hafnium oxide layer into a layer that at least partially has a cubic crystal phase. In other embodiments, the step 1020 of forming the doped gate dielectric layer comprises forming a doped zirconium oxide layer, and the step 1030 of converting comprises converting the doped zirconium oxide layer into a layer that at least partially has a tetragonal crystal phase. In some embodiments, the annealing process is performed with a process temperature that is less than about 500 degrees Celsius.

The method 1000 includes a step 1040 to form a metal-containing gate electrode over the doped gate dielectric layer.

It is understood that the method 1000 may include further steps performed before, during, or after the steps 1010-1040. For example, before the steps 1010-1040 are performed, the method may include the processes performed to form a bottom device of a CFET, as well as steps to form certain components of a top device of the CFET, and bonding the top device to the bottom device. The steps 1010-1040 are performed a part of a formation of a gate structure of the top device of the CFET. For reasons of simplicity, other additional steps are not discussed herein in detail.

In summary, the present disclosure involves using a dipole first approach to fabricate a gate dielectric of a top tier device of a CFET. in more detail, rather than forming a dipole layer over a high-k dielectric layer, the present disclosure forms a dipole layer over an interfacial layer, and then forms a doped amorphous high-k gate dielectric layer over the dipole layer. An annealing process is performed to convert at least partially the amorphous high-k gate dielectric into materials having crystalline phases. A metal-containing gate is then formed over the high-k gate dielectric.

The embodiments of the present disclosure offer advantages over conventional CFET devices. It is understood, however, that other embodiments may offer additional advantages, and not all advantages are necessarily disclosed herein, and that no particular advantage is required for all embodiments. One advantage is the prevention and/or reduction of device damages. In more detail, conventional CFET fabrication involves performing a dipole drive-in process when the top-tier device is fabricated. Such a dipole drive-in process is usually performed with a relatively high temperature, for example, a temperature that is greater than about 500 degrees Celsius. However, by the time that this high temperature dipole drive-in process is performed, the microelectronic components of the bottom-tier device of the CFET have already been formed, which are susceptible to damages caused by high temperatures. In other words, conventional fabrication methods used to fabricate the top-tier device of the CFET may inadvertently damage the bottom-tier device. Here, the unique dipole-first process flow means that no high-temperature dipole drive-in process is needed. The temperatures (e.g., at or below 500 degrees Celsius) associated with the annealing process performed herein are still sufficiently low, such that the microelectronic components of the bottom-tier device are unlikely to be damaged. Another advantage of the present disclosure is improvements in device performance. For example, by converting the amorphous material of the high-k dielectric layer at least partially into a crystalline material, the dielectric constant of the resulting high-k dielectric layer is raised, which leads to an improvement in device performance of the gate structure. Other advantages include compatibility with existing fabrication processes and the case and low cost of implementation.

One aspect of the present disclosure pertains to a device. The device includes an active region. The device includes a dipole layer disposed over the active region. The device includes a doped gate dielectric layer disposed over the dipole layer. The device includes a metal-containing gate electrode disposed over the doped gate dielectric layer.

Another aspect of the present disclosure pertains to a device. The device includes a top-tier transistor that includes a first gate structure. The first gate structure includes a first dipole layer and a first gate dielectric layer disposed over the first dipole layer. The first gate dielectric layer is doped with a dopant. The device includes a bottom-tier transistor vertically bonded to the top-tier transistor. The bottom-tier transistor includes a second gate structure. The second gate structure includes a second gate dielectric layer and a second dipole layer disposed over the second gate dielectric layer. The first dipole layer and the second dipole layer have different material compositions.

Another aspect of the present disclosure pertains to a method. A dipole layer is formed over a semiconductor channel region. A doped gate dielectric layer is formed over the dipole layer. The doped gate dielectric layer contains an amorphous material. Via an annealing process, the amorphous material of the doped gate dielectric layer is converted into a material with at least partially crystal phases. After the doped gate dielectric layer is converted into the layer with partially crystal phases, a metal-containing gate electrode is formed over the doped gate dielectric layer.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
an interfacial layer;
a first layer disposed over the interfacial layer;
a gate dielectric disposed over the first layer; and
a gate electrode disposed over the gate dielectric;
wherein:
the first layer, the gate dielectric, or the gate electrode contains yttrium or scandium; and
a peak concentration level of the yttrium or the scandium occurs within the first layer.

2. The structure of claim 1, wherein the first layer includes a dipole layer.

3. The structure of claim 2, wherein the dipole layer contains lanthanum-containing material.

4. The structure of claim 1, wherein a concentration level of the yttrium or the scandium within the gate dielectric is less than a concentration level of the yttrium or the scandium within the first layer, but is greater than a concentration level of the yttrium or the scandium within the gate electrode.

5. The structure of claim 1, wherein the interfacial layer contains the yttrium or the scandium.

6. The structure of claim 1, further comprising a semiconductor layer disposed below the interfacial layer, wherein the semiconductor layer contains the yttrium or the scandium.

7. The structure of claim 1, wherein the gate dielectric contains a dielectric material that at least partially has a crystal phase.

8. The structure of claim 1, wherein the interfacial layer, the first layer, the gate dielectric, and the gate electrode are components of a first transistor, and wherein the structure further comprises a second transistor that includes:
a further interfacial layer;
a second layer disposed over the further interfacial layer, wherein the second layer is thicker than the first layer in a cross-sectional side view;
a further gate dielectric disposed over second first layer; and
a further gate electrode disposed over the further gate dielectric;
wherein:
the second layer, the further gate dielectric, or the further gate electrode contains the yttrium or the scandium; and
a peak concentration level of the yttrium or the scandium in the second transistor occurs within the second layer.

9. The structure of claim 8, wherein the second transistor has a lower threshold voltage than the first transistor.

10. The structure of claim 8, wherein both the first transistor and the second transistor are n-type transistors.

11. A structure, comprising:
a semiconductor layer, wherein the semiconductor layer has a first concentration level of a dipole material;
a dipole layer disposed over the semiconductor layer in a cross-sectional side view, wherein the dipole layer has a second concentration level of the dipole material; and
a gate structure disposed over the dipole layer in the cross-sectional side view, wherein the gate structure has a third concentration level of the dipole material, wherein the third concentration level is less than the second concentration level but greater than the first concentration level.

12. The structure of claim 11, wherein the dipole material comprises yttrium.

13. The structure of claim 11, wherein the dipole material comprises scandium.

14. The structure of claim 11, further comprising an interfacial layer disposed between the semiconductor layer and the dipole layer, wherein the interfacial layer has a fourth concentration level of the dipole material, and wherein the fourth concentration level is greater than the first concentration level but less than the second concentration level.

15. The structure of claim 11, wherein:
the gate structure includes a gate dielectric disposed over the dipole layer and a gate electrode disposed over the gate dielectric; and
the gate dielectric has a greater concentration level of the dipole material than the gate electrode.

16. The structure of claim 15, wherein the gate dielectric contains a dielectric material that at least partially has a tetragonal crystal phase.

17. The structure of claim 11, wherein the semiconductor layer, the dipole layer, and the gate structure are components of a first n-type field effect transistor (NFET), and wherein the structure further comprises a second NFET that includes:
a further semiconductor layer;
a further dipole layer disposed over the further semiconductor layer in the cross-sectional side view, wherein the further dipole layer is thicker than the dipole layer of the first NFET in the cross-sectional side view; and
a further gate structure disposed over further dipole layer in the cross-sectional side view;
wherein:
the further gate structure has a greater concentration level of the dipole material than the further semiconductor layer but a lower concentration level of the dipole material than the further dipole layer; and
the second NFET has a lower threshold voltage than the first NFET.

18. A structure, comprising:
a first transistor that includes:
a first channel;
a first dipole layer disposed over the first channel; and
a first gate structure disposed over the first dipole layer; and
a second transistor that includes:
a second channel;
a second dipole layer disposed over the second channel, wherein the second dipole layer is thicker than the first dipole layer; and
a second gate structure disposed over the second dipole layer;
wherein:
the second transistor has a lower threshold voltage than the first transistor;
the first transistor and the second transistor contain a dipole material;
a peak concentration level of the dipole material within the first transistor corresponds to a location inside the first dipole layer; and
a peak concentration level of the dipole material within the second transistor corresponds to a location inside the second dipole layer.

19. The structure of claim 18, wherein:
the dipole material comprises yttrium or scandium;
the first gate structure includes a first gate dielectric;
the second gate structure includes a second gate dielectric; and
the first gate dielectric and the second gate dielectric at least partially has a tetragonal crystal phase.

20. The structure of claim 18, wherein:
a concentration of the dipole material within the first gate structure is greater than a concentration of the dipole material within the first channel; and
a concentration of the dipole material within the second gate structure is greater than a concentration of the dipole material within the second channel.
